(19) United States
(12) Patent Application Publication
(10) Pub. No.: US 2013/0269877 A1
(43) Pub. Date: Oct. 17, 2013

(54) SEMICONDUCTOR PROCESSING APPARATUS

(71) Applicants: Yao Hua SUN, Singapore (SG); Eeyian TOH, Singapore (SG)

(72) Inventors: Yao Hua SUN, Singapore (SG); Eeyian TOH, Singapore (SG)

(21) Appl. No.: 13/448,300

(22) Filed: Apr. 16, 2012

(51) Int. Cl. H01L 21/306; B05C 13/00

(52) U.S. Cl. 156/345.51; 118/500

(57) ABSTRACT

A semiconductor processing apparatus includes a wafer supporting unit for supporting a wafer and a wafer holder positioned outside of the wafer supporting unit. The wafer holder further includes a plurality of horizontal parts extending axially around the wafer supporting unit and a plurality of vertical parts vertically extending from the horizontal parts respectively. Topmost surfaces of the vertical parts and a topmost surface of the wafer supporting unit are non-coplanar.

### BACKGROUND OF THE INVENTION

1. Field of the Invention

The present invention relates to a semiconductor processing apparatus, and more particularly, to a semiconductor processing apparatus for supporting a semiconductor wafer.

2. Description of the Prior Art

Modern integrated circuits (ICs) are fabricated on semiconductor wafers by performing various processing steps. Those steps including layer or lamination deposition, photolithography, etching, planarization, thermal treatment, cooling treatment, cleaning, and detecting, etc.

For example, during the photolithography step of semiconductor production, light energy is applied through a reticle mask onto the photoresist material previously formed on the wafer to define circuit patterns on the wafer. Therefore the wafer must be precisely positioned in the processing chamber. In the same concept, the wafer is always required to be precisely positioned during semiconductor processing, even during loading to and unloading from processing chamber. It is observed that if wafer slants due to incorrectly placing, it results breakage or scratch when a track arm, which is used to fetch the semiconductor wafer, comes to retrieve.

Therefore it is always in need to prevent the semiconductor wafer from being incorrectly placed.

### SUMMARY OF THE INVENTION

According to an aspect of the present invention, a semiconductor processing apparatus is provided. The semiconductor processing apparatus includes a wafer supporting unit for supporting a wafer and a wafer holder positioned outside of the wafer supporting unit. The wafer holder further includes a plurality of horizontal parts extending axially around the wafer supporting unit and a plurality of vertical parts vertically extending from the horizontal parts respectively. Topmost surfaces of the vertical parts and a topmost surface of the wafer supporting unit are non-coplanar.

According to the semiconductor processing apparatus provided by the present invention, the wafer holder is provided to prevent wafer from slanting due to incorrect placing. Therefore breakage or scratch that often resulted when a track arm comes to retrieve the wafer is avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective drawing of a semiconductor processing apparatus provided by a preferred embodiment of the present invention.

FIG. 2 is a perspective drawing of the semiconductor processing apparatus having a wafer placed correctly.

FIG. 3 is a top view of the semiconductor processing apparatus having a wafer placed correctly.

FIG. 4 is a top view of the semiconductor processing apparatus allowing a track arm's enter.

FIG. 5A is a schematic drawing respectively illustrating the spatial relationship between the wafer, the track arm, and the semiconductor processing apparatus of the preferred embodiment.

FIG. 5B is a schematic drawing respectively illustrating the spatial relationship between the wafer, the track arm, and a conventional wafer supporting unit.

FIG. 6 is a schematic drawing illustrating a modification to the present invention.

### DETAILED DESCRIPTION

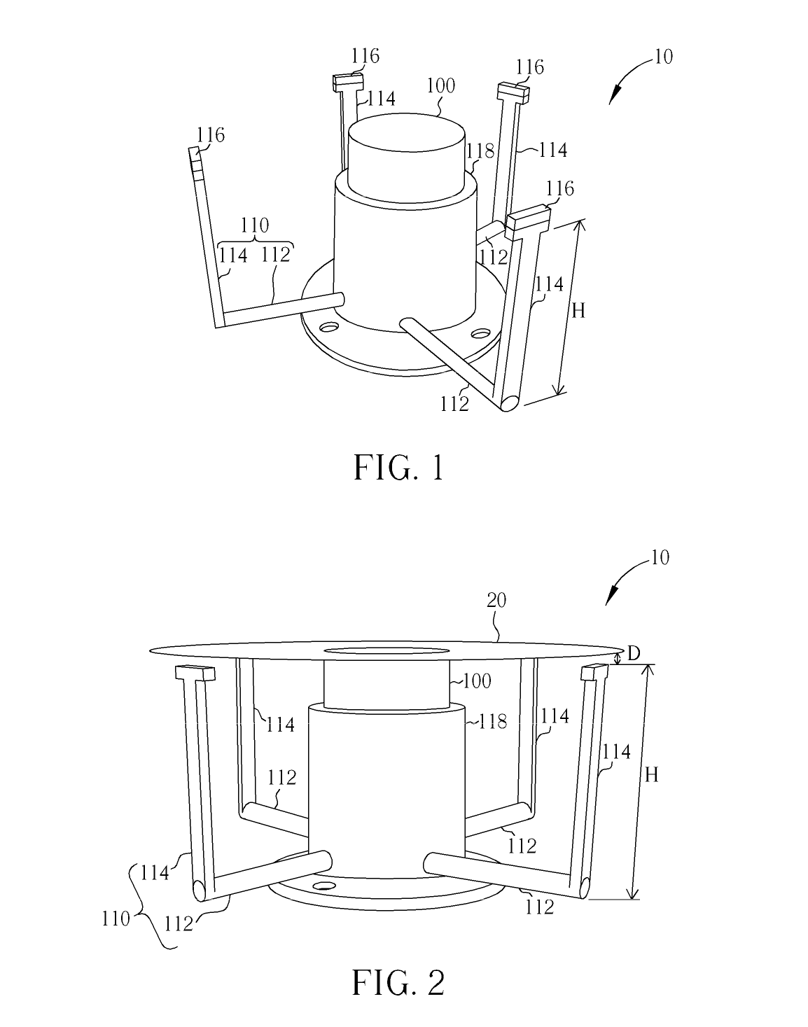

Please refer to FIGS. 1-3, which are a perspective drawing of a semiconductor processing apparatus provided by a preferred embodiment of the present invention. According to the preferred embodiment, the semiconductor processing apparatus 10 includes a wafer supporting unit 100 for supporting a wafer 20 and a wafer holder 110 positioned outside of the wafer supporting unit 100. The wafer supporting unit 100 exemplarily includes a diameter about 40 millimeters (mm). It is noteworthy that the wafer supporting unit 100 can be a vacuum unit.

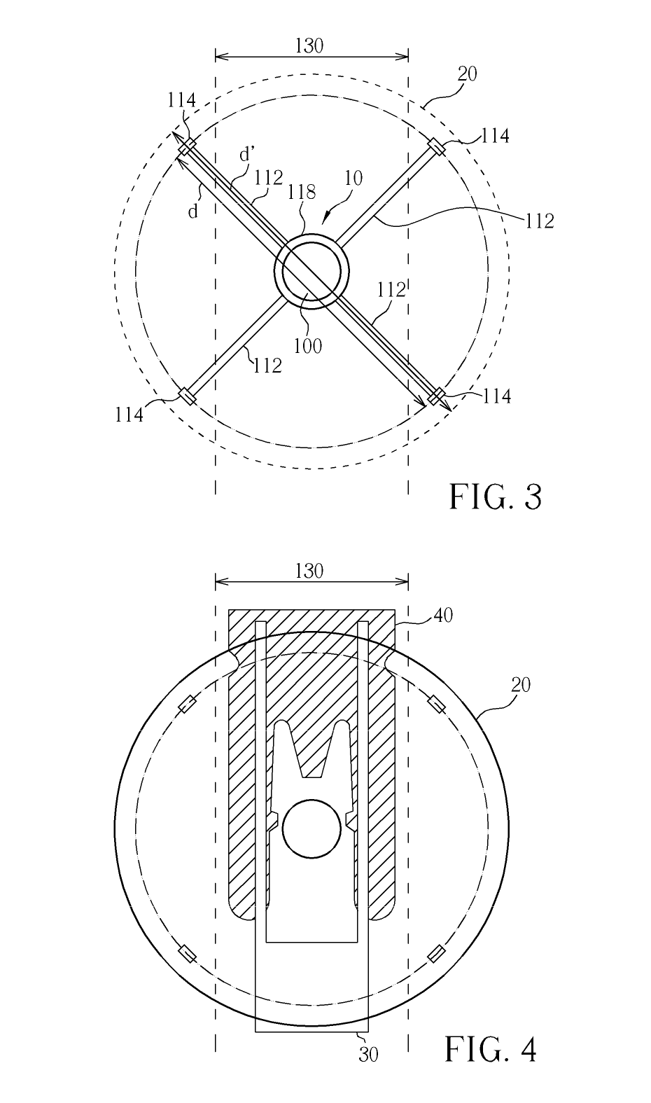

Please still refer to FIGS. 1-3. The wafer holder 110 further includes a plurality of horizontal parts 112 extending axially around the wafer supporting unit 100 and a plurality of vertical parts 114 vertically extending and upwardly from the horizontal parts 112 respectively. Additionally speaking, though the amount of the horizontal parts 112 is 4 in FIGS. 1-3, those skilled in the art would easily realize that the amount of the horizontal parts 112 can be less than or more than that depicted in FIGS. 1-3. In the preferred embodiment, the wafer holder 110 further includes a cylinder casing 118, and the horizontal parts 112 extend from the cylinder casing 118. It is noteworthy that the cylinder casing 118, the horizontal parts 112, and the vertical parts 114 are all monolithic and construct the wafer holder 110. More important, the wafer holder 110 provided by the preferred embodiment is detachable from the wafer supporting unit 100. As shown in FIGS. 1-3, the cylinder casing 118 of the wafer holder 110 sheathes the wafer supporting unit 100. The horizontal parts 112 include a length smaller than a half of a diameter of the wafer 20, which means a diameter “d” of the wafer holder 110 is smaller than a diameter “d′” of the wafer 20 as shown in FIG. 3. For example, when a diameter d′ of the wafer 20 is 300 mm, the diameter d of the wafer holder 110 is about 280 mm, however those skilled in the art would easily realize that the diameter d of the wafer holder 110 is dependant on the diameter d′ of the wafer 20, thus 280 mm is only exemplarily provided but not limited to this.

More important, topmost surfaces of the vertical parts 114 and a topmost surface of the wafer supporting unit 100 are non-coplanar. In detail, the topmost surfaces of the vertical parts 114 are lower than the topmost surface of the wafer supporting unit 100. For example, a vertical deviation D is defined between the topmost surfaces of the vertical parts 114 and the topmost surface of the wafer supporting unit 100, and the vertical deviation D is between 3 mm and 4 mm, but not limited to this. Since the wafer 20 is placed on the topmost surface of the wafer supporting unit 100, the vertical deviation D is also defined as a distance between the bottom surface of the wafer 20 and the topmost surfaces of the vertical parts 114. Furthermore, the semiconductor processing apparatus 10 provided by the preferred embodiment can include a plurality of scratch-protecting parts 116 (shown in FIG. 1) formed on the vertical parts 114, respectively. The scratch-protecting parts 116 are used to protect the wafer 20 from being scratched by the vertical parts 116 and thus include material such as rubber, but not limited to this. It is also noteworthy that topmost surfaces of the scratch-protecting parts 116 and the topmost surface of the wafer supporting unit 100 are non-coplanar. In the same concept, the topmost surfaces of the scratch-protecting parts 116 still are lower than the topmost surface of the wafer supporting unit 100. Accordingly, the vertical parts 114 include a fixed height H, and the fixed height H is about 40 mm. However, those skilled in the art would easily realize that the fixed height H of the vertical parts 114 is determined by making sure that vertical deviation D between the topmost surfaces of the vertical parts 114 and the topmost surface of the wafer supporting unit 100 is between 3 mm and 4 mm, thus 40 mm is only exemplarily provided but not limited to this.

Please refer to FIGS. 3 and 4. The semiconductor processing apparatus 10 of the preferred embodiment further includes an access region 130 defined between the wafer supporting unit 100 and the vertical parts 114. The access region 130 allows a track arm 30 or a tool robot 40, such as an exposure tool robot 40, to retrieve the wafer 20 from the wafer supporting unit 100 for loading to or unloading from the present process station as shown in FIG. 4.

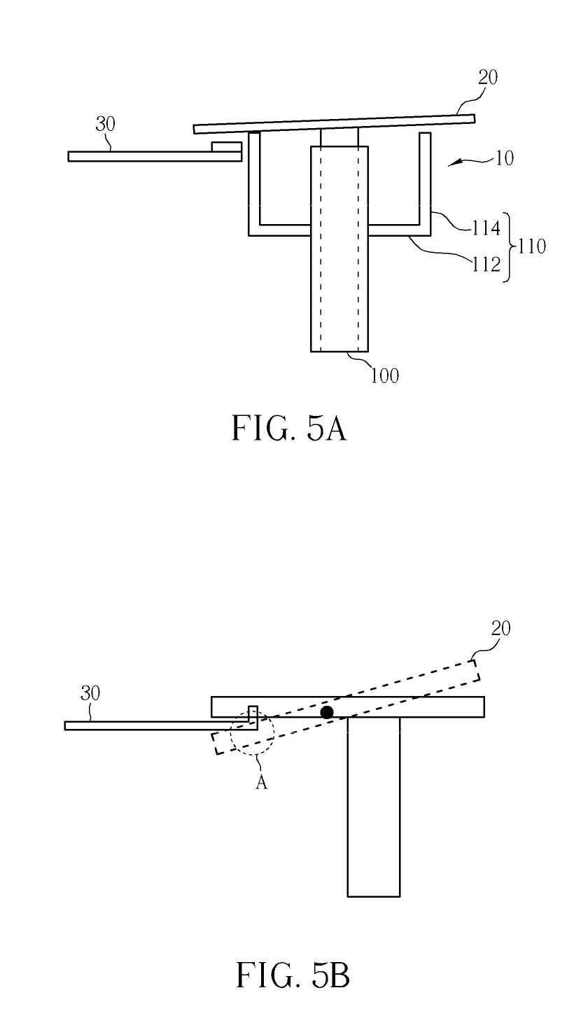

Please refer to FIGS. 5A and 5B, FIG. 5A is a schematic drawing respectively illustrating the spatial relationship between the wafer, the track arm, and the semiconductor processing apparatus of the preferred embodiment and FIG. 5B is a schematic drawing respectively illustrating the spatial relationship between the wafer, the track arm, and conventional wafer supporting unit. As shown in FIG. 5A. since the preferred embodiment provides the wafer holder 110 with the vertical parts 114 that is able to support the wafer 20 when it slants due to incorrectly placing, the wafer 20 is prevented from sliding, and thus breakage is avoided. Moreover, because the wafer holder 110 supports the wafer 20, the track arm 30 is allowed to retrieve the wafer 20 without impacting or scratching the wafer 20 (as emphasized by Circle A shown in FIG. 5B) even the wafer 20 is in the slanting status.

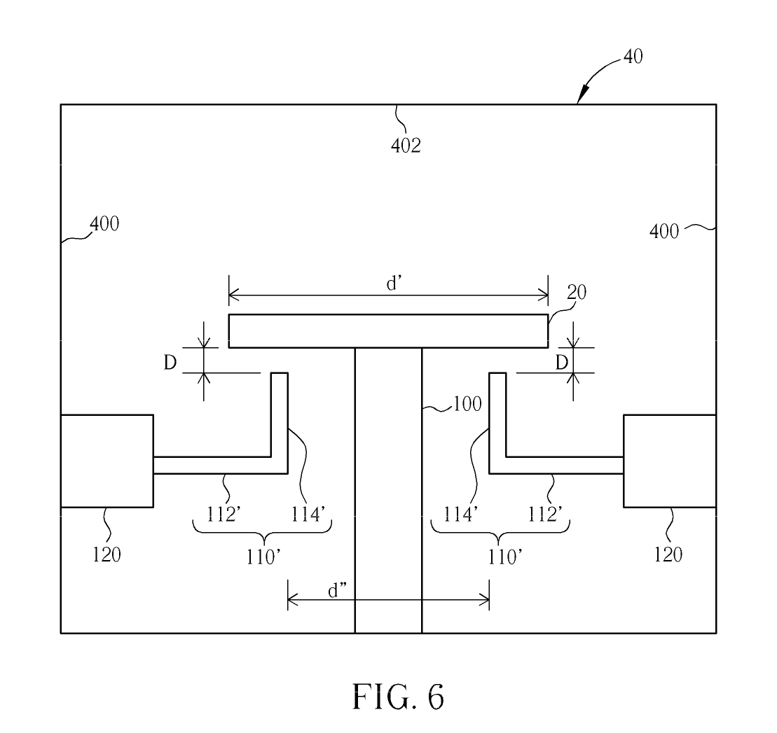

Please refer to FIG. 6, which is schematic drawing illustrating a modification to the present invention. According to the modification, the wafer holder 110′ includes the a plurality of horizontal parts 112′ and a plurality of vertical parts 114′ upwardly extending from the horizontal parts 112′, respectively. It is noteworthy that the horizontal parts 112′ extend to the wafer supporting unit 100 from a support element 120. Furthermore, the support element 120 can be positioned on the inner walls 400 of a chamber 40, or even on the ceiling, which is the top wall 402 of the chamber 40. When the support elements 120 is positioned on the top walls 402 of the chamber, the wafer holder 110′ is hang from the top walls 402. Briefly speaking, the wafer holder 110′ is detachable from the chamber 40. As mentioned above, topmost surfaces of the vertical parts 114′ and a topmost surface of the wafer supporting unit 100 are non-coplanar. In detail, the topmost surfaces of the vertical parts 114′ are lower than the topmost surface of the wafer supporting unit 100. For example, a vertical deviation D is defined between the topmost surfaces of the vertical parts 114′ and the topmost surface of the wafer supporting unit 100, and the vertical deviation D is between 3 mm and 4 mm, but not limited to this. According to the modification, the vertical parts 114′ include a distance from the wafer supporting unit 100. In detail, a distance d″ between to opposite vertical parts 114′ as shown in FIG. 6 is smaller than a diameter d′ of the wafer 20.

According to the semiconductor processing apparatus provided by the present invention, the wafer holder is provided to prevent the semiconductor wafer from sliding and slanting due to incorrect placing. Therefore breakage or scratch that often resulted when a track arm comes to retrieve the wafer is avoided. Moreover, the semiconductor processing apparatus provided by the present invention can be adopted to with all kinds of the wafer supporting unit in the semiconductor processes such as deposition, etching, or photolithograpy process. It also can be used in the discharge stop which is waiting for loading to or unloading from the process station.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor processing apparatus comprising:
a wafer supporting unit for supporting a wafer; and
a wafer holder positioned outside of the wafer supporting unit, the wafer holder further comprising:
a plurality of horizontal parts extending axially around the wafer supporting unit; and
a plurality of vertical parts vertically extending from the horizontal parts respectively, topmost surfaces of the vertical parts and a topmost surfaces of the wafer supporting unit are non-coplanar.

2. The semiconductor processing apparatus according to claim 1, wherein the wafer holder is detachable from the wafer supporting unit.

3. The semiconductor processing apparatus according to claim 1, wherein the horizontal parts and the vertical parts are monolithic.

4. The semiconductor processing apparatus according to claim 1, further comprising a plurality of scratch-protecting parts formed on the vertical parts, respectively.

5. The semiconductor processing apparatus according to claim 4, wherein topmost surfaces of the scratch-protecting parts and the topmost surface of the wafer supporting unit are non-coplanar.

6. The semiconductor processing apparatus according to claim 1, wherein the topmost surfaces of the vertical parts are lower than the topmost surface of the wafer supporting unit.

7. The semiconductor processing apparatus according to claim 6, further comprising a vertical deviation between the topmost surfaces of the vertical parts and the topmost surface of the wafer supporting unit.

8. The semiconductor processing apparatus according to claim 7, wherein the vertical deviation is between 3 millimeters (mm) and 4 mm.

9. The semiconductor processing apparatus according to claim 1, wherein the vertical parts comprise a fixed height.

10. The semiconductor processing apparatus according to claim 9, wherein the fixed height is about 40 mm.

11. The semiconductor processing apparatus according to claim 1, wherein the horizontal parts comprise a length smaller than a half of a diameter of the wafer.

12. The semiconductor processing apparatus according to claim 1, wherein the wafer holder comprises a diameter, and the diameter is about 280 mm.

13. The semiconductor processing apparatus according to claim 1, further comprising an access region between the wafer supporting unit and the vertical parts.

14. The semiconductor processing apparatus according to claim 13, further comprising a track arm for retrieving the wafer from the wafer supporting unit.

15. The semiconductor processing apparatus according to claim 14, wherein the track arm enters the access region for retrieving the wafer from the wafer supporting unit.

16. The semiconductor processing apparatus according to claim 1, wherein the wafer supporting unit comprises a vacuum unit.

17. The semiconductor processing apparatus according to claim 1, wherein the wafer supporting unit comprises a diameter about 40 mm.
